(19) United States
(12) Patent Application Publication
(10) Pub. No.: US 2024/0266178 A1
(43) Pub. Date: Aug. 8, 2024

(54) ELECTROCHEMICAL-MECHANICAL THINNING METHOD AND APPARATUS FOR LARGE-DIAMETER SEMICONDUCTOR WAFERS

(71) Applicant: XI’AN JIAOTONG UNIVERSITY, Xi'an (CN)

(72) Inventors: Xu YANG, Xi'an (CN); Xiaozhe YANG, Xi'an (CN); Zhuangde JIANG, Xi'an (CN)

(73) Assignee: XI’AN JIAOTONG UNIVERSITY, Xi'an (CN)

(21) Appl. No.: 18/434,762

(22) Filed: Feb. 6, 2024

(30) Foreign Application Priority Data
Feb. 7, 2023 (CN) 202310093638.3

(51) Int. Cl. H01L 21/304; B24B 37/11; H01L 21/683

(52) U.S. Cl. CPC H01L 21/304; B24B 37/11; H01L 21/6838

(57) ABSTRACT

Disclosed are electrochemical-mechanical thinning method and apparatus for large-diameter semiconductor wafers. The large-diameter semiconductor wafers are thinned by combining anodizing modification and mechanical grinding. The apparatus includes a grinding tool system, a wafer holding device and a grinding wheel dressing device. The grinding tool system includes a base plate and a cup-shaped grinding wheel. The base plate is taken as a cathode, and the semiconductor wafer is taken as an anode. During thinning, both the cathode and the anode are immersed in an electrolyte. Under the action of an external electric field, the semiconductor wafer is subjected to surface modification and softening. At the same time, an oxide layer and intermediate state products generated by modification are removed together by using the grinding wheel, and the semiconductor wafer is thinned under the combined action of multi-energy fields of electricity, chemistry, machinery and force.

### CROSS-REFERENCE

This application claims priority to Chinese Patent Application No. 202310093638.3, filed on Feb. 7, 2023, the contents of which are hereby incorporated by reference.

### TECHNICAL FIELD

The present disclosure belongs to the technical field of semiconductor wafer processing, in particular to a thinning apparatus and method applicable to a semiconductor wafer of 4 inches or larger, which can be applied to thinning of the semiconductor wafer with low damage and high efficiency.

### BACKGROUND

With the development of electronic information technology, semiconductor components based on silicon (Si) have gradually matured to their physical limits. Wide bandgap semiconductor materials, for example, silicon carbide (SiC), gallium nitride (GaN) and diamond, can work with high reliability even at high temperature, high frequency, and high power. They have become indispensable for manufacturing low-loss, high-frequency, and high-energy power devices. In order to fulfill the use requirements for high-performance power devices, surfaces of final wafers are required to be extremely smooth and damage-free through the machining process of slicing, thinning, double-sided grinding, chemical-mechanical polishing, etc. In these processes, thinning has the greatest removal amount and has non-negligible influence on the thickness, dimensional accuracy, geometric accuracy, surface roughness, and subsurface damage of the wafer.

These wide bandgap semiconductor materials are typical high-hardness and high-brittleness materials, for example, silicon carbide is second to the diamond in terms of hardness. They hardly react with strong acid and alkali for their extremely high chemical stability. In consequence, these materials are difficult to process. At present, diamond tools are mainly used for mechanically thinning silicon carbide wafers. However, a pure mechanical thinning method is costly due to low machining efficiency and heavy tool wear. Besides, a thick damaged layer is inevitably induced on the surface of a processed material through the above method based on hardness differences, and electrical characteristics of the material will be degraded. As a result, the removal amount of following grinding and polishing will be dramatically increased to fully remove the damaged layer.

### SUMMARY

The present disclosure provides an electrochemical-mechanical thinning method and apparatus for large-diameter semiconductor wafers, which greatly reduce the wear of a grinding wheel, a damaged layer of the wafer, and the removal amount of subsequent grinding and polishing.

In order to achieve the above objective, an electrochemical-mechanical thinning apparatus for large-diameter semiconductor wafers according to the present disclosure includes a grinding tool system, where the grinding tool system is mounted on a lifting device, a wafer holding device is arranged below the grinding tool system, the grinding tool system includes a base plate and a grinding wheel, and the grinding wheel is fixed to the lower end of the base plate;

the base plate is connected to a cathode conductive slip ring, an anode conductive slip ring is mounted on the wafer holding device, and the anode conductive slip ring is connected to a semiconductor wafer to be thinned during thinning; and

an outer ring of the cathode conductive slip ring is connected to a negative electrode of a power supply unit, an outer ring of the anode conductive slip ring is connected to a positive electrode of the power supply unit, and the base plate and the semiconductor wafer to be thinned are in contact with an electrolyte during thinning.

Further, the semiconductor wafer is fixed to the wafer holding device through vacuum adsorption or adhesion.

Further, a top of the wafer holding device is provided with a recess, and a vacuum adsorption plate is arranged in the recess; a through hole is provided in a bottom of the recess, and the through hole is connected to a vacuum pump through a tube and a rotary joint; and the vacuum adsorption plate is configured to clamp the semiconductor wafer to be thinned.

Further, the power supply unit is an electrochemical workstation, a counter electrode of the electrochemical workstation is connected to the outer ring of the cathode conductive slip ring, and a working electrode thereof is connected to the outer ring of the anode conductive slip ring.

Further, the wafer holding device is mounted in an electrolyte tank for containing the electrolyte.

Further, a dressing device for dressing the grinding wheel is arranged below the grinding tool system, the dressing device is arranged in the electrolyte tank, the electrolyte tank is fixed on a slide block, and the slide block is slidably connected to a slide rail mounted on a bottom plate.

Further, an outlet of the electrolyte tank is connected to an input end of a peristaltic pump through a pipe, an output end of the peristaltic pump is connected to an input end of an electrolyte filter, and an output end of the electrolyte filter is connection with an inlet of the electrolyte tank through a pipe.

Further, a thermostatic water tank is arranged on the pipe between the output end of the electrolyte filter and the inlet of the electrolyte tank.

An electrochemical-mechanical thinning method for large-diameter semiconductor wafers based on the above thinning apparatus includes:
S1, cleaning and drying a semiconductor wafer;
S2, measuring a thickness H of the semiconductor wafer, and determining a thinning removal amount H-h according to a target thinning thickness h;
S3, fixing the semiconductor wafer to a wafer holding device;
S4, moving the wafer holding device to a position below a grinding tool system, and moving the grinding tool system downwards until a bottom of a grinding wheel is in contact with a surface of the semiconductor wafer;
S5, setting electrochemical anodizing modification parameters through a power supply unit;
S6, setting the thinning removal amount and a feed rate, and powering on drive motors of the grinding tool system and the wafer holding device;
S7, powering on the power supply unit and applying a voltage/current; and
S8, performing thinning, where the semiconductor wafer undergoes anodizing reaction with an electrolyte under the action of an electric field, and an oxide layer that has a hardness lower than a hardness of a semiconductor material is generated on the surface of the semiconductor wafer, and is simultaneously removed through relative movement between the grinding wheel and the semiconductor wafer until the wafer is thinned to the target thickness h.

Further, before S5, the method includes: powering on the peristaltic pump, turning on the electrolyte filter, and when a temperature of the electrolyte needs to be controlled, turning on a thermostatic water tank and setting a target temperature.

Compared with the prior art, the present disclosure at least has the following beneficial effects:
1) Thinning efficiency is high.

During thinning in the present disclosure, the semiconductor wafer is subjected to electrochemical anodizing modification, such that the semiconductor wafer with an extremely high hardness can be efficiently modified and softened. At the same time, the wafer surface including a wafer base material, an oxidation modification layer and an intermediate oxide is removed by using the grinding wheel, The electrochemical anodizing and mechanical grinding are performed at the same time, so as to realize highly efficient wafer thinning and greatly reduce surface roughness and the damaged layer of the wafer after thinning.
2) Wear of the grinding wheel is small and the cost is reduced.

The electrochemical modification can reduce the surface hardness of the wafer, which effectively reduces grinding force and wear of the grinding wheel, and thus reduces the processing cost.
3) Environmental performance is remarkable since no strong acid, strong alkali and strong oxidants are needed.

During processing, under the action of an external electric field, electrons and holes in the wafer are separated, and the holes move towards an interface between the wafer surface and the electrolyte. The holes have strong oxidation property and react with water molecules in the electrolyte, so as to implement anodizing modification. Since no additional strong acid, strong alkali and strong oxidants are needed, the wafer is manufactured in an environment-friendly way.
4) The processing apparatus is simple in structure and the processing method is easy to implement.

The process parameters of the processing apparatus include a grinding amount, feed rate, a rotation speed of a polishing tool, a rotation speed of the wafer, a rotation speed of the dressing device, a type and a concentration of the electrolyte, a potential difference between wafer and a counter electrode, and a current density, and they can be adjusted according to actual processing conditions for achieving optimal processing effects.

Further, in order to ensure the processing effect, it is necessary to dress the cup-shaped diamond grinding wheel in time. The dressing device is moved in a horizontal direction to a position below the grinding tool system and is in contact with a surface of the grinding wheel. The cup-shaped diamond grinding wheel is online dressed through relative movement between the grinding tool system and the dressing device after the grinding tool system and the dressing device rotate.

According to the method, the mechanical thinning and the electrochemical anodizing modification are combined, and the base plate serves as the cathode and the semiconductor wafer serves as the anode. During the processing, both the cathode and anode are immersed in the electrolyte. Under the action of the external electric field, the semiconductor wafer undergoes the anodizing reaction with the electrolyte for surface modification and softening. At the same time, an oxide layer and intermediate state products generated during surface modification are removed together by using the diamond grinding wheel, and the semiconductor wafer is thinned under the combined action of multi-energy fields of electricity, chemistry, machinery, and force.

### BRIEF DESCRIPTION OF FIGURES

FIG. 1 is a schematic diagram of an electrochemical-mechanical thinning apparatus for semiconductor wafers according to the present disclosure;

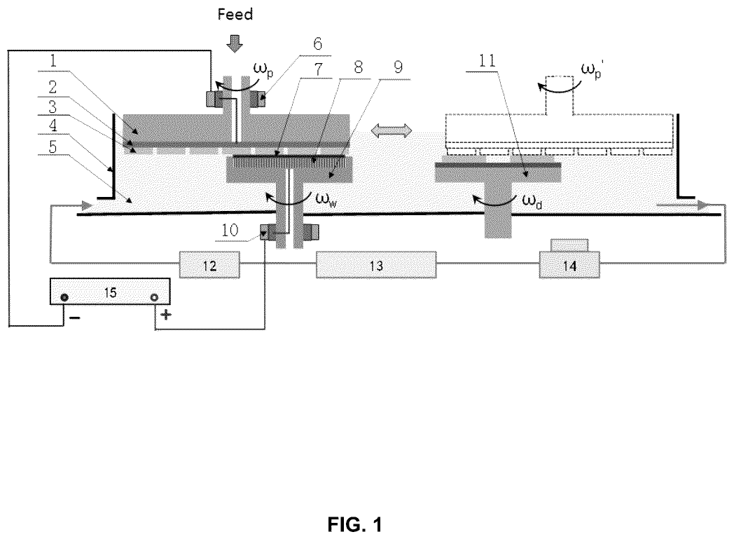

FIG. 2 is a principle diagram of an electrochemical-mechanical thinning method for semiconductor wafers according to the present disclosure; and

FIG. 3 is a schematic diagram of a perspective view of an electrochemical-mechanical thinning apparatus for semiconductor wafers according to the present disclosure.

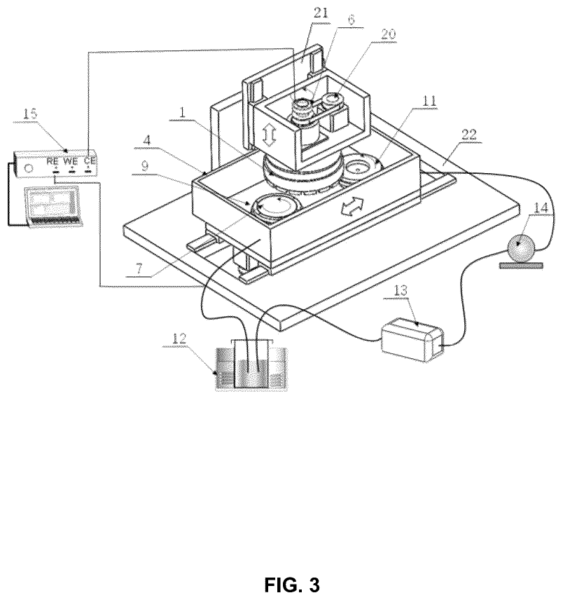

In the figures: 1. grinding tool system, 2. base plate, 3. grinding wheel, 4. electrolyte tank, 5. electrolyte, 6. cathode conductive slip ring, 7. semiconductor wafer, 8. vacuum adsorption plate, 9. wafer holding device, 10. anode conductive slip ring, 11. grinding wheel dresser, 12. thermostatic water tank, 13. electrolyte filter, 14. peristaltic pump, 15. electrochemical workstation, 16. single diamond abrasive particle, 17. oxide layer, 18. shallow damaged layer, 19. deep damaged layer, 20. first servo motor, 21. electric lifting plate, and 22. bottom plate.

### DETAILED DESCRIPTION

In order to make objectives and technical solutions of the present disclosure clearer and easier to understand, the present disclosure will be further described in detail with reference to accompanying drawings and in conjunction with embodiments. The specific embodiments described herein are merely used for explaining the present disclosure rather than limiting the present disclosure.

An electrochemical-mechanical thinning apparatus for semiconductor wafers according to the present disclosure includes a grinding tool system 1, an electrolyte tank 4, a cathode conductive slip ring 6, a wafer holding device 9, an anode conductive slip ring 10, a thermostatic water tank 12, an electrolyte filter 13, a peristaltic pump 14, an electrochemical workstation 15, an electric lifting plate 21, a bottom plate 22 and a dressing device for dressing a grinding wheel 3. The dressing device is a dresser 11.

The grinding tool system 1 is fixed to the electric lifting plate 21, and may adjust a feed amount and a feed rate during thinning of the semiconductor wafer.

The grinding tool system 1 includes a hollowed grinding spindle, the base plate 2 and the grinding wheel 3. The hollowed grinding spindle penetrates the grinding tool system 1 and may be driven by a first servo motor 20 through a belt and a pulley to rotate. The grinding wheel 3 is fixed to a lower end of the base plate 2, and a diameter of a lower end face of the grinding wheel 3 is larger than a diameter of a semiconductor wafer 7. The base plate 2 is taken as a cathode and the semiconductor wafer 7 to be processed is taken as an anode. During processing, both the cathode and anode are immersed in an electrolyte 5, such as NaCl, KCl, NaNO₃, KNO₃ or NaCO₃.

The base plate 2 is made of metal and fixed as a cathode plate to a lower portion of the hollowed grinding spindle. The base plate 2 is connected to an output shaft of the first servo motor 20 through the hollowed grinding spindle, the pulley, and the belt. The cathode conductive slip ring 6 is arranged at an outer side of the hollowed grinding spindle, and a wire is arranged in the hollowed grinding spindle. One end of the wire is connected to the base plate 2, and the other end thereof is connected to an inner ring of the cathode conductive slip ring 6. An outer ring of the cathode conductive slip ring 6 is connected to a counter electrode of the electrochemical workstation 15 or a negative electrode of a direct current power supply through a wire.

An applied negative potential may pass through an outer ring lead and an inner ring lead of the cathode conductive slip ring 6 above the base plate 2 in turn, and then reach the base plate 2. An applied positive potential may pass through an outer ring lead and an inner ring lead of the anode conductive slip ring 10 below the wafer holding device 9 in turn, be connected to a vacuum adsorption plate 8, and finally be in connection with the semiconductor wafer 7. The negative potential is applied to the base plate 2 (cathode plate), and the positive potential is applied to the semiconductor wafer 7 to form a potential difference.

The grinding wheel 3 is fixed to the lower end of the base plate 2, and is driven by a numerical control system. In this way, the grinding wheel 3 and the semiconductor wafer 7 are in contact with each other and move relative to each other. The grinding wheel 3 may preferably be selected as, but not limited to, a cup-shaped diamond grinding wheel. A grinding wheel that is made from aluminium oxide and a cerium oxide with different properties and hardnesses may also be selected for removing a surface of the semiconductor wafer and thinning the wafer. The wafer surface includes a wafer surface base material, an oxidation modification layer and intermediate state products.

Two slide rails are fixed to the bottom plate 22, slide blocks are slidably mounted on the slide rails, and the electrolyte tank 4 is fixed to the slide blocks. Upper portions of the wafer holding device 9 and the dresser 11 are located in the electrolyte tank 4. During thinning, a surface of the base plate 2 (cathode plate) and the surface of the semiconductor wafer 7 are both immersed in the electrolyte 5. The counter electrode of the electrochemical workstation 15 is connected to the outer ring of the conductive slip ring 6 through a wire, and a working electrode is connected to an outer ring of the anode conductive slip ring 10 through a wire. The electrochemical workstation 15, the semiconductor wafer 7, the electrolyte 5, and the base plate 2 (cathode plate) form a closed loop.

The electrochemical workstation 15 may be replaced with a power supply. When the electrochemical workstation 15 is replaced with the power supply, a negative electrode of a power supply unit is connected to the outer ring of the conductive slip ring 6, and a positive electrode thereof is connected to the outer ring of the anode conductive slip ring 10.

The electrolyte 5 may also be supplied through a pipe, as long as both the semiconductor wafer 7 and the base plate 2 are guaranteed to be in contact with the electrolyte.

The electrolyte tank 4 contains the electrolyte 5. During polishing, the base plate 2, the diamond grinding wheel 3 and the semiconductor wafer 7 are immersed in the electrolyte 5. The electrolyte 5 serves as an anodizing medium and provides a liquid environment for thinning grinding. Through relative movement between the grinding tool system 1 and the semiconductor wafer 7, impurities such as cut chips generated by grinding flow away from the surface of the semiconductor wafer 7 along with the electrolyte, such that the wafer surface is prevented from being scratched and quality of the processed surface is guaranteed. The electrolyte may also be supplied cyclically in a flowing manner.

The semiconductor wafer 7 is fixed to an upper surface of the wafer holding device 9 through vacuum adsorption or adhesion, and is driven by a second servo motor. The second servo motor is connected to a main shaft of the wafer holding device through a pulley, and the semiconductor wafer 7 rotates axially along with the wafer holding device 9. The grinding wheel 3 is fixed to the base plate 2 (the base plate in the present disclosure is made of a metal material). After being driven, the grinding wheel 3 is in contact with the semiconductor wafer 7 and moves relative to the semiconductor wafer 7.

In the case of vacuum adsorption fixing, a top of the wafer holding device 9 is provided with a recess, a middle of the recess is a vacuum adsorption plate 8, and a bottom of the recess is provided with a circular through hole. The circular through hole is connected to a vacuum pump through a tube and a rotary joint. The semiconductor wafer 7 is placed on an upper end of the vacuum adsorption plate 8, and the semiconductor wafer 7 can be fixed through vacuum adsorption by powering on the vacuum pump.

The vacuum adsorption plate 8 is made of a conductive material and has conductivity. Under the condition of vacuum adsorption, the semiconductor wafer 7 is closely in contact with the vacuum adsorption plate 8, so as to be electrically conductive with the vacuum adsorption plate. The anode conductive slip ring 10 is arranged at an outer side of a hollowed shaft of the wafer holding device 9, and a wire is arranged at an inner side of the hollowed shaft. One end of the lead wire is connected to the vacuum adsorption plate 8, and the other end thereof is connected to the inner ring of the anode conductive slip ring 10. The outer ring of the anode conductive slip ring 10 is connected to the working electrode of the electrochemical workstation 15 or the positive electrode of the direct current power supply through the lead wire, and the working electrode of the electrochemical workstation 15 is finally connected to the semiconductor wafer 7.

The thermostatic water tank 12 is used to control a temperature of the electrolyte 5. The thermostatic water tank 12 is connected to an inlet of the electrolyte tank 4 through a pipe and connected to an output end of an electrolyte filter 13 through another pipe. An input end of the electrolyte filter 13 is connected to an output end of the peristaltic pump 14, and an input end of the peristaltic pump 14 is connected to an outlet of the electrolyte tank 4 through a pipe.

The electrolyte filter 13 filters off and removes impurities such as cut chips generated during thinning. The peristaltic pump may be used to filter off the polishing impurities in the electrolyte and circulate the electrolyte, so as to prevent polishing residues from scratching the wafer surface and reuse the electrolyte.

The peristaltic pump 14 provides power for the electrolyte circulation and may adjust the circulation rate of the electrolyte.

The grinding wheel dresser 11 is located on a workbench in a horizontal direction of the apparatus, and may move in the horizontal direction. The grinding wheel dresser 11 is driven to rotate by a third servo motor. When a lead screw drives the slide block to move the dresser 11 to a position below the grinding tool system 1, relative movement is generated, such that the cup-shaped diamond grinding wheel 3 can be dressed.

The grinding tool system 1 is located at an upper portion of the thinning apparatus, and the wafer holding device and the dressing device are arranged in parallel at a lower portion of the thinning apparatus and may move laterally, such that switching between wafer thinning and grinding tool dressing may be implemented.

The semiconductor wafer 7 is a silicon wafer, a silicon carbide wafer, a gallium nitride wafer, etc.

An external electric field may be implemented in the form of one or more of the electrochemical workstation, the direct current power supply, a potentiostat, a battery, etc.

An electrochemical-mechanical thinning method for large-diameter semiconductor wafers based on the above electrochemical-mechanical thinning apparatus for large-diameter semiconductor wafers specifically includes:
S1, a semiconductor wafer 7 is cleaned by a wet cleaning method to remove dust, impurities and oxides on a surface of the semiconductor wafer 7, and then dried by a nitrogen gun.
S2, a thickness H of the semiconductor wafer is measured, and a thinning removal amount (H-h) is determined according to a target thinning thickness h.
S3, the semiconductor wafer 7 is fixed to an upper end of a wafer holding device 9 through vacuum adsorption.
S4, a slide block where a grinding wheel dresser 11 and the wafer holding device 9 are located is moved, and the grinding wheel dresser 11 is moved to a position below a grinding tool system 1. An electric lifting plate 21 where the grinding tool system 1 is located is driven to move downwards until a bottom of a grinding wheel 3 is in contact with a surface of the grinding wheel dresser 11 and the grinding wheel reaches a position for dressing start, and a dressing amount is set.
S5, respective drive motors of the grinding tool system 1 and the dresser 11 are powered on, and the cup-shaped grinding wheel 3 is dressed according to the set dressing amount. After finishing dressing, the drive motors are powered off, and the grinding tool system 1 is lifted upwards through the electric lifting plate 21.
S6, the slide block where the grinding wheel dresser 11 and the wafer holding device 9 are located is moved, and the wafer holding device 9 is moved to a position below the grinding tool system 1 until an entire surface to be processed of the semiconductor wafer 7 is within an orthographic projection range of the grinding wheel 3. A specific position is adjusted according to eccentricity requirements of the semiconductor wafer 7 and the grinding wheel 3. The electric lifting plate 21 is driven to drive the grinding tool system 1 to move downwards until the bottom of the cup-shaped diamond grinding wheel 3 is in contact with the surface of the semiconductor wafer 7, and the cup-shaped diamond grinding wheel 3 reaches a position for thinning start.
S7, a peristaltic pump 14 is powered on, and an electrolyte filter 13 and a thermostatic water tank 12 are powered on for cyclic filtration on and temperature control over the electrolyte (the temperature may not be controlled).
S8, electrochemical anodizing modification parameters are set through electrochemical workstation 15, and the electrochemical anodizing modification parameters include a voltage, a current, time, etc.
S9, the thinning removal amount and a feed rate are set, and drive motors of the grinding tool system 1 and the wafer holding device 9 is powered on.
S10, the electrochemical workstation 15 is powered on for applying the voltage/current.
S11, thinning is performed, the semiconductor wafer 7 undergoes anodizing reaction with an electrolyte 5 under the action of an electric field, and an oxide that has a hardness lower than a hardness of a semiconductor wafer 7 is generated on the surface of the semiconductor wafer 7, and is simultaneously removed through relative movement between the grinding wheel 3 and the semiconductor wafer 7 until a specified grinding position is reached and the wafer is thinned to the target thickness h.
S12, after the thinning is completed, waste liquid is sucked, collected and discharged, a vacuum adsorption device is powered off, and a thinned wafer is taken down.

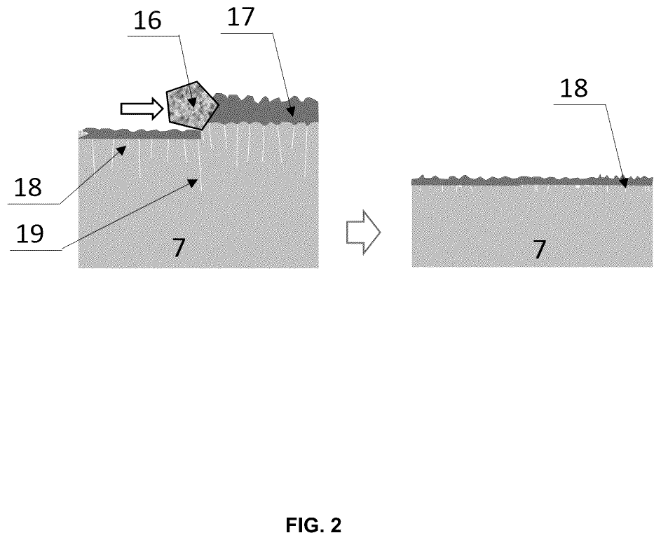

With reference to FIG. 2, a working principle of the present disclosure is as follows: before processing, a deep and large damaged layer 19 on the surface of the semiconductor wafer 7 caused by wire cutting is subjected to electrochemical anodizing modification, so as to generate a soft oxide layer 17. Then, the oxide layer 17 is removed by diamond abrasive particles 16, and the semiconductor wafer 7 is thinned and the deep damaged layer 19 is removed accordingly. Since the diamond grinding wheel is used during thinning, and the diamond abrasive particles is harder than the oxide layer and a semiconductor wafer body, the diamond abrasive particles will remove the semiconductor wafer body while removing the damaged layer, and a shallow damaged layer 18 is caused on the surface of the semiconductor wafer accordingly. The damage also reacts with the electrolyte quickly under the action of electric field to generate an oxide layer 17.

What is claimed is:

1. An electrochemical-mechanical thinning apparatus for large-diameter semiconductor wafers, comprising a grinding tool system (1), wherein the grinding tool system (1) is mounted on a lifting device, a wafer holding device (9) is arranged below the grinding tool system (1), the grinding tool system (1) comprises a base plate (2) and a grinding wheel (3), and the grinding wheel (3) is fixed to a lower end of the base plate (2);
the base plate (2) is connected to a cathode conductive slip ring (6), an anode conductive slip ring (10) is mounted on the wafer holding device (9), and the anode conductive slip ring (10) is connected to a semiconductor wafer (7) to be thinned during thinning; and
an outer ring of the cathode conductive slip ring (6) is connected to a negative electrode of a power supply unit, an outer ring of the anode conductive slip ring (10) is connected to a positive electrode of the power supply unit, and the base plate (2) and the semiconductor wafer (7) to be thinned are in contact with an electrolyte (5) during thinning.

2. The electrochemical-mechanical thinning apparatus for large-diameter semiconductor wafers according to claim 1, wherein the semiconductor wafer (7) is fixed to the wafer holding device (9) through vacuum adsorption or adhesion.

3. The electrochemical-mechanical thinning apparatus for large-diameter semiconductor wafers according to claim 2, wherein a top of the wafer holding device (9) is provided with a recess, and a vacuum adsorption plate (8) is arranged in the recess; a through hole is provided in a bottom of the recess, and the through hole is connected to a vacuum pump through a tube and a rotary joint; and the vacuum adsorption plate (8) is configured to clamp the semiconductor wafer (7) to be thinned.

4. The electrochemical-mechanical thinning apparatus for large-diameter semiconductor wafers according to claim 1, wherein the power supply unit is an electrochemical workstation (15), a counter electrode of the electrochemical workstation (15) is connected to the outer ring of the cathode conductive slip ring (6), and a working electrode thereof is connected to the outer ring of the anode conductive slip ring (10).

5. The electrochemical-mechanical thinning apparatus for large-diameter semiconductor wafers according to claim 1, wherein the wafer holding device (9) is mounted in an electrolyte tank (4) for containing the electrolyte (5).

6. The electrochemical-mechanical thinning apparatus for large-diameter semiconductor wafers according to claim 5, wherein a dressing device for dressing the grinding wheel (3) is arranged below the grinding tool system (1), the dressing device is arranged in the electrolyte tank (4), the electrolyte tank (4) is fixed on a slide block, and the slide block is slidably connected to a slide rail mounted on a bottom plate (22).

7. The electrochemical-mechanical thinning apparatus for large-diameter semiconductor wafers according to claim 5, wherein an outlet of the electrolyte tank (4) is connected to an input end of a peristaltic pump (14) through a pipe, an output end of the peristaltic pump (14) is connected to an input end of an electrolyte filter (13), and an output end of the electrolyte filter (13) is in connection with an inlet of the electrolyte tank (4) through a pipe.

8. The electrochemical-mechanical thinning apparatus for large-diameter semiconductor wafers according to claim 7, wherein a thermostatic water tank (12) is arranged on the pipe between the output end of the electrolyte filter (13) and the inlet of the electrolyte tank (4).

9. An electrochemical-mechanical thinning method for large-diameter semiconductor wafers based on the thinning apparatus according to claim 1, comprising:
S1, cleaning and drying a semiconductor wafer (7);
S2, measuring a thickness H of the semiconductor wafer (7), and determining a thinning removal amount H-h according to a target thinning thickness h;
S3, fixing the semiconductor wafer (7) to a wafer holding device (9);
S6, moving the wafer holding device (9) to a position below a grinding tool system (1), and moving the grinding tool system (1) downwards until a bottom of a grinding wheel (3) is in contact with a surface of the semiconductor wafer (7);
S7, setting electrochemical anodizing modification parameters through a power supply unit;
S8, setting the thinning removal amount and a feed rate, and powering on drive motors of the grinding tool system (1) and the wafer holding device (9);
S9, powering on the power supply unit and applying a voltage/current; and
S10, performing thinning, wherein the semiconductor wafer (7) undergoes anodizing reaction with an electrolyte under the action of an electric field, and an oxide that has a hardness lower than a hardness of a semiconductor wafer is generated on the surface of the semiconductor wafer, and is simultaneously removed through relative movement between the grinding wheel (3) and the semiconductor wafer (7) until the wafer is thinned to the target thickness h.

10. The electrochemical-mechanical thinning method for large-diameter semiconductor wafers according to claim 9, wherein before S7, a peristaltic pump (14) is powered on, and an electrolyte filter (13) is turned on, and when a temperature of the electrolyte needs to be controlled, a thermostatic water tank (12) is turned on and a temperature thereof is set.
